(19) United States
(12) Patent Application Publication
(10) Pub. No.: US 2025/0364899 A1
(43) Pub. Date: Nov. 27, 2025

(54) BIDIRECTIONAL DC/DC CONVERTER, POWER INTERRUPTION PROTECTION CIRCUIT, AND SEMICONDUCTOR DEVICE

(71) Applicant: ROHM CO., LTD., Kyoto (JP)

(72) Inventor: Akira URYU, Kyoto (JP)

(21) Appl. No.: 19/208,023

(22) Filed: May 14, 2025

(30) Foreign Application Priority Data
May 21, 2024 (JP) 2024-082739

(51) Int. Cl. H02M 1/088; H02J 9/06; H02M 3/158; H03K 17/687

(52) U.S. Cl. CPC H02M 1/088; H02J 9/061; H02M 3/1584; H03K 17/687; H03K 2217/0063; H03K 2217/0072

(57) ABSTRACT

A bidirectional DC/DC converter includes a high-side switch, a low-side switch, and a controller capable of being switched between a step-up mode and a step-down mode and configured to generate a control signal to control operations of the high-side switch and the low-side switch so that the bidirectional DC/DC converter functions as a step-up converter in the step-up mode and functions as a step-down converter in the step-down mode. At least one of the high-side switch or the low-side switch includes a plurality of switching elements of a same type connected in parallel, and the controller operates the plurality of switching elements of the same type in conjunction with each other in the step-up mode or the step-down mode.

### CROSS REFERENCE TO RELATED APPLICATION

The present invention claims priority under 35 U.S.C. § 119 to Japanese Patent Application No. 2024-082739, filed on May 21, 2024, the entire contents of which are incorporated herein by reference.

### TECHNICAL FIELD

The present disclosure relates to a bidirectional DC/DC converter, a power interruption protection circuit, and a semiconductor device.

### BACKGROUND

Various devices require stable supply of power. For example, in a storage device such as an SSD (Solid State Drive), when the supply of power from a power supply is interrupted momentarily, there is a risk that stored data may be lost.

In the related art, there is disclosed a technique in which a power supply voltage is boosted to charge a capacitor, and when the supply of power from the power supply to a device is interrupted, the voltage of the charged capacitor is stepped down to supply power to the device.

A step-up converter is used to step up a power supply voltage, and a step-down converter is used to step down a capacitor voltage. Both converters use high-side and low-side transistors, but a current supply capacity required for the transistors differs between the step up and the step down. In the related art, there is disclosed that low-side transistors having different on-resistances are operated for the step up and step down.

### BRIEF DESCRIPTION OF DRAWINGS

The accompanying drawings, which are incorporated in and constitute a part of the specification, illustrate embodiments of the present disclosure.

FIG. 1 is a block diagram of a system according to a first embodiment.

FIG. 2 is a block diagram of a power interruption protection circuit for explaining a configuration of a bidirectional DC/DC converter according to the first embodiment.

FIG. 3 is a timing chart for explaining an example of an operation of the bidirectional DC/DC converter according to the first embodiment when the bidirectional DC/DC converter functions as a step-up converter.

FIG. 4 is a timing chart for explaining in more detail an operation during a charging period of the bidirectional DC/DC converter functioning as the step-up converter.

FIG. 5 is a timing chart for explaining an example of an operation of the bidirectional DC/DC converter according to the first embodiment when the bidirectional DC/DC converter functions as a step-down converter.

FIG. 6 is a top view of an example of a layout of a low-side switch in a semiconductor chip according to the first embodiment.

FIG. 7 is a block diagram of a power interruption protection circuit for explaining a configuration of a bidirectional DC/DC converter according to a comparative technique.

FIG. 8 is a top view of a layout of a low-side switch in a semiconductor chip according to the comparative technique.

FIG. 9 is a block diagram of a power interruption protection circuit for explaining a configuration of a bidirectional DC/DC converter according to a second embodiment.

FIG. 10 is a timing chart for explaining an example of an operation of the bidirectional DC/DC converter according to the second embodiment when the bidirectional DC/DC converter functions as a step-up converter.

FIG. 11 is a timing chart for explaining in more detail an operation during a charging period of the bidirectional DC/DC converter functioning as the step-up converter.

FIG. 12 is a timing chart for explaining an example of an operation of the bidirectional DC/DC converter according to the second embodiment when the bidirectional DC/DC converter functions as a step-down converter.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview

The overview of some exemplary embodiments of the present disclosure will be described. This overview presents, in a simplified form, some concepts of one or more embodiments, as a prologue to the detailed description which will be presented later, and for the purpose of basic understanding of the embodiments, but it is not intended to limit the scope of the invention or the disclosure. This overview is not a comprehensive overview of all possible embodiments, and it is intended to neither identify key elements of all embodiments nor delineate the scope of some or all aspects. For the sake of convenience in description, “an embodiment” may be used to refer to one embodiment (example or modification) or a plurality of embodiments (examples or modifications) disclosed herein.

A bidirectional DC/DC converter according to one embodiment includes: a high-side switch; a low-side switch; and a controller capable of being switched between a step-up mode and a step-down mode and generates a control signal to control operations of the high-side switch and the low-side switch so that the bidirectional DC/DC converter functions as a step-up converter in the step-up mode and functions as a step-down converter in the step-down mode. At least one of the high-side switch or the low-side switch includes a plurality of switching elements of a same type connected in parallel. The controller operates the plurality of switching elements of the same type in conjunction with each other in the step-up mode or the step-down mode.

With this configuration, by operating the plurality of switching elements of the same type in conjunction with each other, it is possible to implement control suitable for each of the step-up mode and the step-down mode. In addition, since the plurality of switching elements are of the same type, the layout design is simplified. Therefore, it is possible to provide a bidirectional DC/DC converter that implements appropriate control with a simple design.

In one embodiment, the high-side switch may include a high-side transistor constituted with a MOS transistor. The low-side switch may include a plurality of low-side transistors constituted with MOS transistors of the same type and connected in parallel. The controller may control the operations of the high-side switch and the low-side switch so as to step up a voltage of an input/output line connected to a load and charge a backup capacitor by alternately repeating a charging period and a discharging period in the step-up mode, and to step down a charging voltage of the backup capacitor in the step-down mode and supply the stepped-down voltage to the input/output line.

In one embodiment, the controller may operate one low-side transistor of the plurality of low-side transistors in one cycle of the charging period and the discharging period in the step-up mode, and operate all of the plurality of low-side transistors in synchronization with each other in the step-down mode.

In one embodiment, the controller may switch which of the plurality of low-side transistors is to be operated among for each cycle of the charging period and the discharging period in the step-up mode.

In one embodiment, when the plurality of low-side transistors are first to m-th (m is an integer equal to or greater than 2) low-side transistors, the controller may select an operating low-side transistor one by one from the first to m-th low-side transistors in this order for each cycle in the step-up mode and operate the selected low-side transistor.

In one embodiment, the high-side switch may include a plurality of high-side transistors constituted with MOS transistors of the same type and connected in parallel. The low-side switch may include a low-side transistor constituted with a MOS transistor. The controller may control the operations of the high-side switch and the low-side switch so as to step up a voltage of an input/output line connected to a load and charge a backup capacitor by alternately repeating a charging period and a discharging period in a synchronous rectification manner in the step-up mode, and to step down a charging voltage of the backup capacitor in the step-down mode and supply the stepped-down voltage to the input/output line.

In one embodiment, the controller may operate one of the plurality of high-side transistors in one cycle of the charging period and the discharging period in the step-up mode, and operate all of the plurality of high-side transistors in synchronization with each other in the step-down mode.

In one embodiment, the controller may switch which of the plurality of high-side transistors is to be operated for each cycle of the charging period and the discharging period in the step-up mode.

In one embodiment, when the plurality of high-side transistors are first to n-th (n is an integer equal to or greater than 2) high-side transistors, the controller may select an operating high-side transistor one by one from the first to n-th high-side transistors in this order for each cycle in the step-up mode and operate the selected high-side transistor.

In one embodiment, the bidirectional DC/DC converter may further include: a plurality of drivers of a same type that operate the plurality of corresponding switching elements of the same type, respectively, in response to the control signal.

In one embodiment, each of the plurality of switching elements of the same type may form a pair with a corresponding one of the plurality of drivers of the same type. Each of the pairs may be arranged side by side in one direction with a same layout.

A power interruption protection circuit according to one embodiment includes: the above-described bidirectional DC/DC converter; and a backup capacitor. The controller controls the operations of the high-side switch and the low-side switch so as to step up a voltage of an input/output line connected to a load and charge the backup capacitor in the step-up mode, and to step down the charging voltage of the backup capacitor in the step-down mode and supply the stepped-down voltage to the input/output line. A mode of the controller is switched to the step-down mode in response to detection of an interruption in supply of power from a power supply to a load.

A semiconductor device according to one embodiment includes: a capacitor connection terminal to which a backup capacitor is to be connected; an input/output terminal to be connected to an input/output line via an inductor; a ground terminal to be connected to a ground; a high-side switch provided between the capacitor connection terminal and the input/output terminal; a low-side switch provided between the input/output terminal and the ground terminal; and a controller capable of being switched between a step-up mode and a step-down mode and generates a control signal to control operations of the high-side switch and the low-side switch so as to step up a voltage of the input/output line and charge the backup capacitor in the step-up mode, and to step down a voltage of the backup capacitor in the step-down mode and supply the stepped-down voltage to the input/output line. At least one of the high-side switch or the low-side switch includes a plurality of switching elements of a same type connected in parallel. The controller operates the plurality of switching elements of the same type in conjunction with each other in the step-up mode or the step-down mode.

With this configuration, by operating the plurality of switching elements of the same type in conjunction with each other, it is possible to implement control suitable for each of the step-up mode and the step-down mode. In addition, since the plurality of switching elements are of the same type, the layout design is simplified. Therefore, it is possible to provide a semiconductor device for a bidirectional DC/DC converter that implements appropriate control with a simple design.

In one embodiment, the semiconductor device may be configured to be integrated in one semiconductor substrate.

### EMBODIMENTS

Preferred embodiments will now be described with reference to the drawings. Like or equivalent components, members, and processes illustrated in each drawing are given like reference numerals and a repeated description thereof will be properly omitted. Further, the embodiments are presented by way of example only and are not intended to limit the present disclosure and invention, and any features or combination thereof described in the embodiments may not necessarily be essential to the present disclosure and invention.

In this specification, the expression “a member A is connected to a member B” includes not only a case where the member A and the member B are physically directly connected to each other, but also a case where the member A and the member B are indirectly connected to each other via any other member that does not substantially affect an electrical connection state between the members A and B or does not impair functions and effects achieved by combinations of the members A and B.

Similarly, the expression “a member C is connected (installed) between a member A and a member B” includes to not only a case where the member A and the member C or the member B and the member C are directly connected to each other, but also a case where the member A and the member C or the member B and the member C are indirectly connected to each other via any other member that does not substantially affect an electrical connection state between the members A and C or the members B and C or does not impair functions and effects achieved by combinations of the members A and C or the members B and C.

Further, in the present disclosure, symbols attached to electrical signals such as voltage signals and current signals, or circuit elements such as resistors, capacitors, and inductors, represent respective voltage values, current values, or circuit constants (resistance, capacitance, and inductance) as necessary.

### First Embodiment

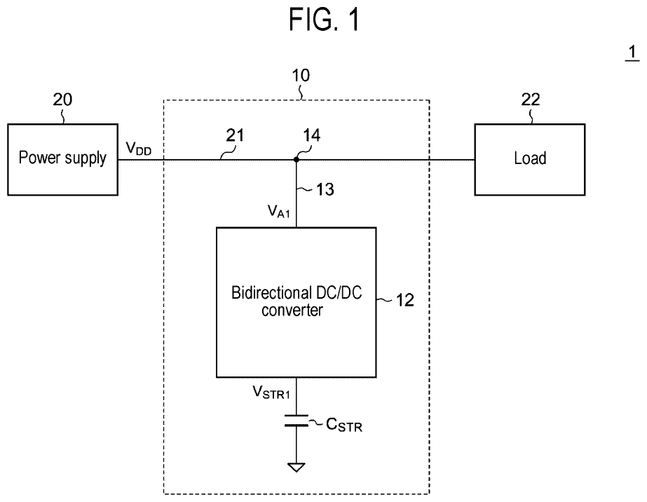

FIG. 1 is a block diagram of a system 1 according to a first embodiment. The system 1 mainly includes a power interruption protection circuit 10, a power supply 20, and a load 22. The power interruption protection circuit 10 is provided between the power supply 20 and the load 22. The power supply 20 and the load 22 are connected to each other via a transmission line 21.

The power supply 20 generates a power supply voltage V_{DD}. Power corresponding to the power supply voltage V_{DD} is supplied to the load 22 via the transmission line 21. The load 22 may be any device that operates according to the supplied power, for example, a storage device such as an SSD.

The power interruption protection circuit 10 includes a bidirectional DC/DC converter 12, an input/output line 13, and a backup capacitor C_{STR}. The bidirectional DC/DC converter 12 is connected to a connection node 14 of the transmission line 21 via the input/output line 13. Although not shown in FIG. 1, a fuse (for example, an electronic fuse) may be provided on the transmission line 21 between the connection node 14 and the power supply 20.

The power interruption protection circuit 10 boosts (steps up) a voltage V_{A1} of the input/output line 13 corresponding to the power supply voltage V_{DD} to charge the backup capacitor C_{STR}. In response to detection of an interruption in the supply of power from the power supply 20 to the load 22, the power interruption protection circuit 10 steps down a charging voltage V_{STR1} of the backup capacitor C_{STR} and supplies the stepped-down charging voltage V_{STR1} to the input/output line 13, thereby supplying power to the load 22. As a result, even if the supply of power from the power supply 20 to the load 22 is interrupted momentarily, the power interruption protection circuit 10 may supply the power to the load 22. As a result, for example, when the load 22 is a storage device, loss of stored data is suppressed.

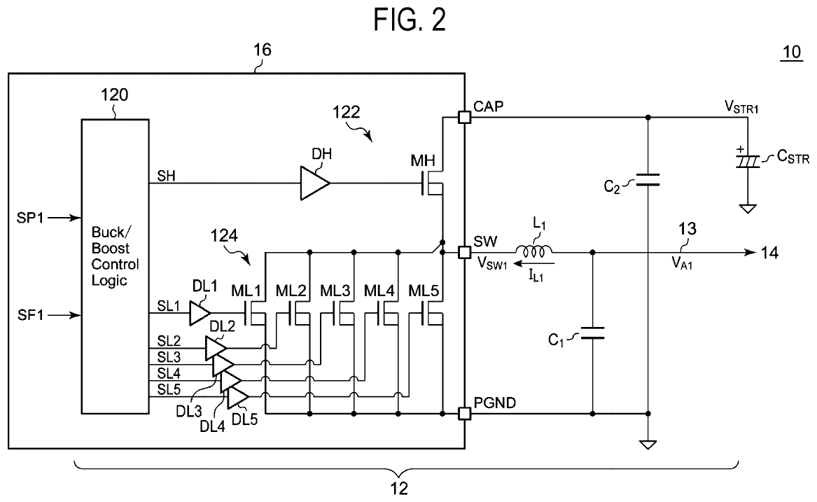

FIG. 2 is a block diagram of the power interruption protection circuit 10 for explaining a configuration of the bidirectional DC/DC converter 12 according to the first embodiment. The bidirectional DC/DC converter 12 has functions as both a step-up converter and a step-down converter, and is configured to be capable of switching between these functions.

The bidirectional DC/DC converter 12 according to this embodiment mainly includes a controller 120, a high-side switch 122, a low-side switch 124, an inductor L₁, and capacitors C₁ and C₂.

A portion of the bidirectional DC/DC converter 12 may be integrated on one semiconductor substrate. Specifically, a semiconductor device 16 having the controller 120, the high-side switch 122, and the low-side switch 124 may be integrated on one semiconductor substrate. The semiconductor device 16 may be configured as an IC (Integrated Circuit) having a PLP (Power Loss Protection) function.

The semiconductor device 16 further includes a capacitor connection terminal CAP to which the backup capacitor C_{STR} is to be connected, a switching terminal SW (input/output terminal) to which the input/output line 13 is to be connected via the inductor L₁, and a ground terminal PGND to which the ground is to be connected.

The controller 120 generates control signals SH and SL1 to SL5 to control operations of the high-side switch 122 and the low-side switch 124. The controller 120 may switch between a step-up mode and a step-down mode. In the step-up mode, the controller 120 controls the operations of the high-side switch 122 and the low-side switch 124 so that the bidirectional DC/DC converter 12 functions as the step-up converter. In the step-down mode, the controller 120 controls the operations of the high-side switch 122 and the low-side switch 124 so that the bidirectional DC/DC converter 12 functions as the step-down converter.

In the step-up mode, the controller 120 according to this embodiment controls the operations of the high-side switch 122 and the low-side switch 124 so as to step up the voltage V_{A1} of the input/output line 13 to charge the backup capacitor C_{STR} by alternately repeating a charging period and a discharging period. In addition, in the step-down mode, the controller 120 controls the operations of the high-side switch 122 and the low-side switch 124 so as to step down the charging voltage V_{STR1} of the backup capacitor C_{STR} and supply the stepped-down voltage to the input/output line 13.

A mode of the controller 120 may be switched to the step-down mode, for example, in response to detection of an interruption in the supply of power from the power supply 20 to the load 22. The detection of the interruption in the power supply may be, for example, detection of an abnormality in the power supply 20 itself or the transmission line 21, or detection of a drop in the power supply voltage V_{DD} (for example, the power supply voltage V_{DD} becoming lower than a threshold voltage). This detection is performed by a detection circuit (not shown), and a signal SP1 indicating the detection result may be transmitted to the controller 120.

The controller 120 may control the operations of the high-side switch 122 and the low-side switch 124 according to a feedback signal SF1. The feedback signal SF1 may be a feedback signal of the voltage V_{A1} of the input/output line 13 (e.g., a signal obtained by dividing the voltage V_{A1}) and a feedback signal of the charging voltage V_{STR1} of the backup capacitor C_{STR} (e.g., a signal obtained by dividing the charging voltage V_{STR1}).

The high-side switch 122 is provided between the capacitor connection terminal CAP and the switching terminal SW. The low-side switch 124 is provided between the switching terminal SW and the ground terminal PGND. At least one of the high-side switch 122 or the low-side switch 124 includes a plurality of switching elements of the same type connected in parallel. The controller 120 operates the plurality of switching elements of the same type in conjunction with each other in the step-up mode or step-down mode. In this embodiment, the low-side switch 124 includes a plurality of switching elements of the same type connected in parallel.

The high-side switch 122 includes a high-side transistor MH and a high-side driver DH. The high-side transistor MH is constituted with a transistor, specifically, an N-channel MOS (Metal Oxide Semiconductor) transistor. A source of the high-side transistor MH is connected to the switching terminal SW, and a drain of the high-side transistor MH is connected to the capacitor connection terminal CAP. The high-side driver DH operates (turns on and off) the high-side transistor MH in response to the control signal SH from the controller 120.

The low-side switch 124 includes a plurality of low-side transistors ML1 to ML5 connected in parallel and a plurality of low-side drivers DL1 to DL5 of the same type connected in parallel. The number of pairs of low-side transistors and low-side drivers in this embodiment is five, but may be two to four, or six or more.

Each of the low-side transistors ML1 to ML5 in this embodiment is constituted with a transistor, specifically, an N-channel MOS transistor. A source of each of the low-side transistors ML1 to ML5 is connected to the ground terminal PGND, and a drain of each of the low-side transistors ML1 to ML5 is connected to the switching terminal SW.

Each of the plurality of low-side transistors ML1 to ML5 has an on-resistance that may implement a sufficient current supply capacity in the step-up mode. In addition, the plurality of low-side transistors ML1 to ML5 have a combined resistance that may implement a sufficient current supply capacity in the step-down mode when all of them are in an on state. Specifically, when all of the plurality of low-side transistors ML1 to ML5 are in an on state, the combined resistance thereof is one-fifth of the on-resistance of one low-side transistor.

Each of the low-side drivers DL1 to DL5 operates (turns on and off) a corresponding one of the plurality of low-side transistors ML1 to ML5 in response to an input control signal among the control signals SL1 to SL5.

The inductor L₁ and the capacitors C₁ and C₂ are externally attached to the semiconductor device 16. One end of the inductor L₁ is connected to the switching terminal SW, and the other end of the inductor L₁ is connected to the input/output line 13. The capacitor C₁ is provided between the input/output line 13 and the ground. The capacitor C₂ is provided between the capacitor connection terminal CAP and the ground. The backup capacitor C_{STR} is provided between the capacitor connection terminal CAP and the ground.

A circuit configuration of the power interruption protection circuit 10 according to this embodiment has been described above. Hereinafter, an example of the operation of the power interruption protection circuit 10 according to this embodiment will be described.

An example of the operation of the bidirectional DC/DC converter 12 when it functions as the step-up converter, that is, when the controller 120 is in the step-up mode, will be described. The bidirectional DC/DC converter 12 according to this embodiment functions as an asynchronous rectification step-up converter. Specifically, in the step-up mode, the controller 120 turns off the high-side transistor MH and operates the low-side transistors ML1 to ML5.

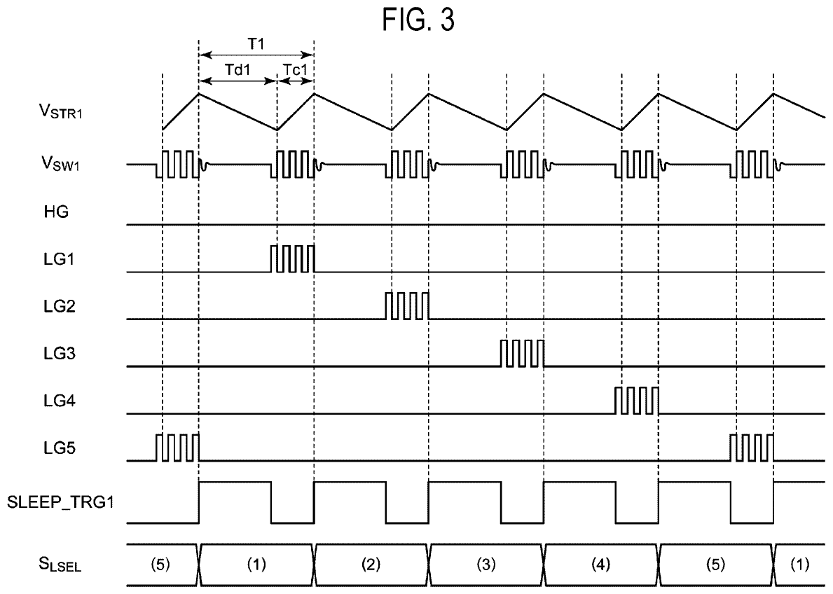

FIG. 3 is a timing chart for explaining an example of the operation of the bidirectional DC/DC converter 12 according to the first embodiment when it functions as the step-up converter. FIG. 3 shows the charging voltage V_{STR1} of the backup capacitor C_{STR}, a voltage V_{SW1} of the switching terminal SW, a voltage HG between the gate and source of the high-side transistor MH, voltages LG1 to LG5 between the gate and source of the low-side transistors ML1 to ML5, a sleep trigger SLEEP_TRG1, and a selection signal S_{LSEL} in order from the top. The sleep trigger SLEEP_TRG1 and the selection signal S_{LSEL} are internal signals of the controller 120.

In this embodiment, in the step-up mode, each of the voltages LG1 to LG5 is controlled so that a charging period Tc1 and a discharging period Td1 are repeated alternately. In the charging period Tc1, the backup capacitor C_{STR} is charged, and in the discharging period Td1, the backup capacitor C_{STR} is naturally discharged.

In the step-up mode, the voltage HG between the gate and source of the high-side transistor MH is 0 V, and the high-side transistor MH is maintained in the off state. The gate voltage of the high-side transistor is a voltage obtained by adding the voltage HG between the gate and the source of the high-side transistor MH to the voltage V_{SW1} of the switching terminal SW.

In this embodiment, the sleep trigger SLEEP_TRG1 becomes a high level when the charging voltage V_{STR1} reaches a predetermined voltage, and becomes a low level when the charging voltage V_{STR1} drops to the predetermined voltage. Therefore, the sleep trigger SLEEP_TRG1 alternates between the high level and the low level for each cycle T1 (=Tc1+Td1) of the charging period Tc1 and the discharging period Td1. During the period when the sleep trigger SLEEP_TRG1 is in the low level, the low-side transistors ML1 to ML5 are turned on and off.

The controller 120 according to this embodiment operates one of the low-side transistors ML1 to ML5 during one cycle T1 of the charging period Tel and the discharging period Td1 in the step-up mode. Specifically, during each cycle, one of the low-side transistors ML1 to ML5 is turned on and off. This prevents the low-side transistors ML1 to ML5 from operating more than necessary, and reduces switching loss due to parasitic capacitance.

Which of the low-side transistors ML1 to ML5 operates in each cycle is determined by the selection signal S_{LSEL}. In this embodiment, the selection signal S_{LSEL} switches in response to the sleep trigger SLEEP_TRG1 becoming the high level. In FIG. 3, a number j (j is 1 to 5) indicated in the selection signal S_{LSEL} indicates an operating low-side transistor MLj (j is 1 to 5).

The controller 120 according to this embodiment switches which of the plurality of low-side transistors ML1 to ML5 to operate for each cycle T1 of the charging period Tel and the discharging period Td1. This makes it possible to distribute the operating burden to the plurality of low-side transistors ML1 to ML5, and thus improve the lifespan of the low-side transistors ML1 to ML5, as compared to when one low-side transistor is continuously operated.

Here, the plurality of low-side transistors ML1 to ML5 are referred to as first to m-th (m is an integer equal to or greater than 2) low-side transistors. The controller 120 according to this embodiment selects an operating low-side transistor one by one from the first to m-th low-side transistors in that order every cycle T1, and operates the selected low-side transistor. In this embodiment, m=5.

Specifically, as shown in FIG. 3, in one cycle following the cycle T1 in which the low-side transistor ML1 is turned on and off, the low-side transistor ML2 is turned on and off. In one cycle following this, the low-side transistor ML3 is turned on and off. In one cycle following one cycle in which the low-side transistor ML5 is turned on and off, the low-side transistor ML1 is turned on and off. This makes it possible to distribute the burden on the low-side transistors ML1 to ML5 more efficiently, and thus more effectively improve the lifespan of the low-side transistors ML1 to ML5.

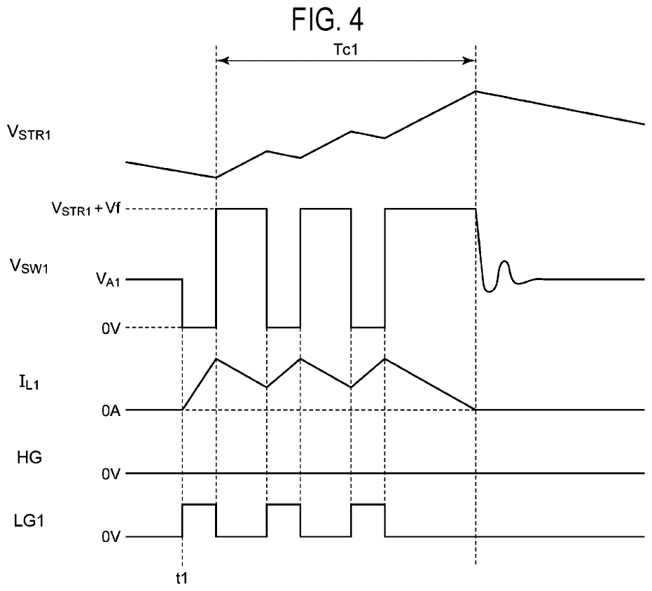

FIG. 4 is a timing chart for explaining in more detail the operation during the charging period Tc1 of the bidirectional DC/DC converter 12 functioning as the step-up converter. FIG. 4 shows the charging voltage V_{STR1} of the backup capacitor C_{STR}, the voltage V_{SW1} of the switching terminal SW, a current I_{L1} flowing through the inductor L₁, the voltage HG between the gate and the source of the high-side transistor MH, and the voltage LG1 between the gate and the source of the low-side transistor ML1 in order from the top. A direction of the current I_{L1} from the input/output line 13 toward the switching terminal SW is considered positive.

FIG. 3 shows an example in which the low-side transistors ML1 to ML5 are turned on and off four times in each cycle T1, while FIG. 4 shows an example in which the low-side transistors ML1 to ML5 are turned on and off three times. In addition, FIG. 4 shows the voltage LG1 between the gate and the source of the low-side transistor ML1, but even if the voltage LG1 is replaced with the voltages LG2 to LG5, the charging voltage V_{STR1}, the voltage V_{SW1}, and the current I_{L1} will change in the same manner.

As shown in FIG. 4, before timing t1 (the discharging period), the switching terminal SW is in Hi-Z, and the voltage V_{SW1} is the voltage V_{A1} of the input/output line 13. After timing t1, the low-side transistor ML1 is turned on and off repeatedly, causing the current I_{L1} to flow.

When the low-side transistor ML1 is turned on (LG1 is at a high level), a current path is formed via the low-side transistor ML1, and the current I_{L1} becomes large. When the low-side transistor ML1 is turned off, a current corresponding to the current I_{L1} is supplied to the backup capacitor C_{STR} via a body diode of the high-side transistor MH, and the backup capacitor C_{STR} is charged.

Here, when the low-side transistor ML1 is turned on, the voltage V_{SW1} is 0 V, and when the low-side transistor ML1 is turned off, the voltage V_{SW1} is V_{STR1}+Vf. Vf is a forward voltage of the body diode of the high-side transistor MH.

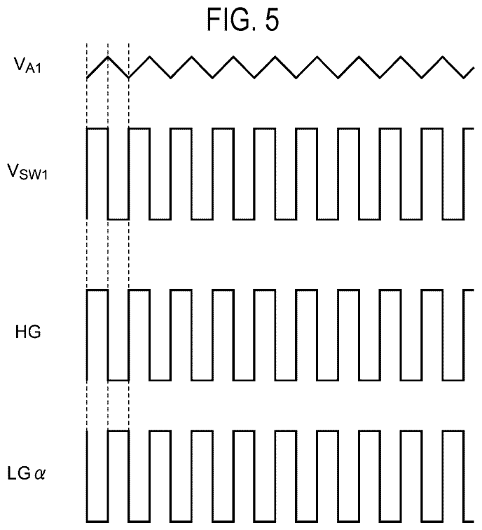

FIG. 5 is a timing chart for explaining an example of the operation of the bidirectional DC/DC converter 12 according to the first embodiment when it functions as the step-down converter. FIG. 5 shows the voltage V_{A1} of the input/output line 13, the voltage V_{SW1} of the switching terminal SW, the voltage HG between the gate and the source of the high-side transistor MH, and a voltage LGα (α: 1 to 5) between the gate and the source of a low-side transistor MLα (α: 1 to 5) in order from the top.

In the step-down mode, the controller 120 controls the operations of the high-side transistor MH and the low-side transistors ML1 to ML5 in a synchronous rectification manner. Specifically, the controller 120 alternately turns on and off the high-side transistor MH and the low-side transistors ML1 to ML5.

As shown in FIG. 5, the high-side transistor MH and the low-side transistor MLα are alternately turned on and off, so that the voltage V_{A1} becomes a voltage obtained by stepping down the charging voltage V_{STR1}. This voltage V_{A1} may be supplied to the load 22 when, for example, an interruption in the supply of power from the power supply 20 to the load 22 is detected. This makes it possible to supply the power to the load 22 even when the supply of power from the power supply 20 to the load 22 is interrupted.

In the step-down mode, since the power is supplied to the load 22 as needed, the low-side switch 124 is required to have a higher current supply capacity than when charging the backup capacitor C_{STR}. In order to achieve a sufficient current supply capacity, the low-side transistors ML1 to ML5 need to be operated in a linear region.

In the step-down mode, the controller 120 according to this embodiment operates all of the plurality of low-side transistors ML1 to ML5 in synchronization with each other. Specifically, the controller 120 simultaneously turns on and off all of the low-side transistors ML1 to ML5. This makes it possible to reduce the combined resistance of the low-side transistors ML1 to ML5 as compared to when one low-side transistor is operated. As a result, it becomes possible to more reliably operate the low-side transistors ML1 to ML5 in the linear region, thereby improving the current supply capacity of the low-side switch 124.

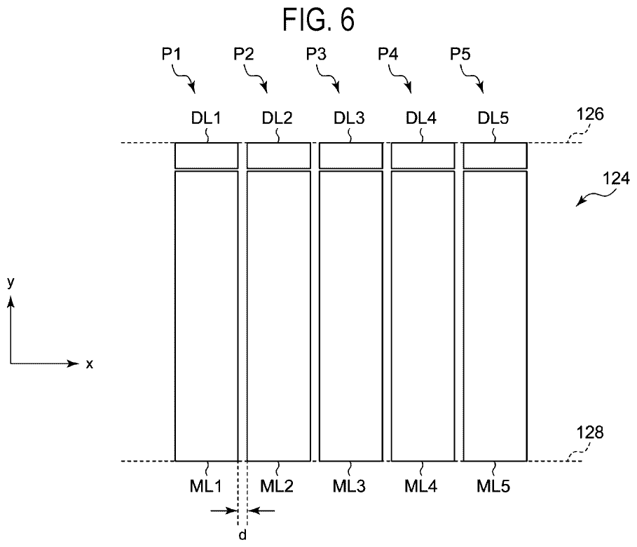

FIG. 6 is a top view of an example of a layout of the low-side switch 124 in a semiconductor chip according to the first embodiment. The low-side transistors ML1 to ML5 and the low-side drivers DL1 to DL5 according to this embodiment have a rectangular shape. However, the shapes of the low-side transistors ML1 to ML5 and the low-side drivers DL1 to DL5 are not limited thereto. In FIG. 6, the x-axis represents a width direction of the low-side transistors ML1 to ML5, and the y-axis perpendicular to the x-axis represents a length direction of the low-side transistors ML1 to ML5.

As shown in FIG. 6, the plurality of low-side transistors ML1 to ML5 form pairs P1 to P5 with the plurality of low-side drivers DL1 to DL5, respectively. The pairs P1 to P5 are arranged side by side in one direction with the same layout.

Specifically, the low-side transistors ML1 to ML5 have the same shape, and the low-side drivers DL1 to DL5 have the same shape. Further, in the pairs P1 to P5, a positional relationship between the low-side transistors ML1 to ML5 and the low-side drivers DL1 to DL5 is also the same. Specifically, in the pairs P1 to P5, the low-side transistors ML1 to ML5 and the low-side drivers DL1 to DL5 are arranged side by side in the y-axis direction.

The pairs P1 to P5 are arranged side by side in the x-axis direction with a same interval d between them. Ends of the low-side drivers DL1 to DL5 on the opposite side to the low-side transistors ML1 to ML5 are aligned along an imaginary straight line 126 parallel to the x-axis. In addition, ends of the low-side transistors ML1 to ML5 on the opposite side to the low-side drivers DL1 to DL5 are aligned along an imaginary straight line 128 parallel to the x-axis.

According to the low-side switch 124 related to this embodiment, since the pairs P1 to P5 have the same layout, when the layout of one pair is designed, the same design may be applied to the other pairs, making the layout design simple. In addition, since the pairs P1 to P5 have the same layout and are arranged side by side in one direction, it is possible to make a current flow evenly through the low-side transistors ML1 to ML5. As a result, the concentration of a current in some low-side transistors is suppressed, making it possible to achieve higher reliability.

The configuration and operation of the power interruption protection circuit 10 according to this embodiment have been described above. The bidirectional DC/DC converter 12 included in the power interruption protection circuit 10 according to this embodiment includes the controller 120, the high-side switch 122, and the low-side switch 124. At least one of the high-side switch 122 or the low-side switch 124 (in this embodiment, the low-side switch 124) includes the plurality of switching elements (the low-side transistors ML1 to ML5) of the same type connected in parallel. The controller 120 operates the plurality of switching elements (the low-side transistors ML1 to ML5) of the same type in conjunction with each other in the step-up mode or the step-down mode (in this embodiment, the step-down mode).

With this configuration, by operating the plurality of switching elements of the same type in conjunction with each other, it is possible to implement control suitable for each of the step-up mode and the step-down mode. In addition, since the plurality of switching elements are of the same type, the layout design is simplified. Therefore, in accordance with the bidirectional DC/DC converter 12 according to this embodiment, it is possible to implement appropriate control with a simple design.

The advantages of the bidirectional DC/DC converter 12 according to this embodiment become clearer when compared with a comparative technique to be described below.

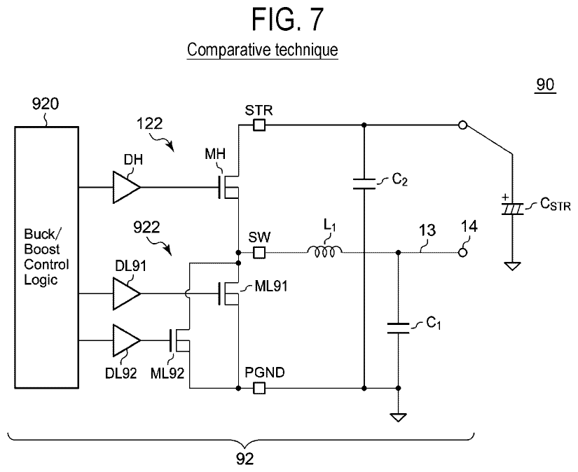

FIG. 7 is a block diagram of a power interruption protection circuit 90 for explaining a configuration of a bidirectional DC/DC converter 92 according to a comparative technique. The power interruption protection circuit 90 according to the comparative technique includes the bidirectional DC/DC converter 92 and a backup capacitor C_{STR}.

The bidirectional DC/DC converter 92 includes a controller 920, a high-side switch 122, a low-side switch 922, an inductor L₁, capacitors C₁ and C₂, a capacitor connection terminal CAP, a switching terminal SW, and a ground terminal PGND. The bidirectional DC/DC converter 92 according to the comparative technique is different from the bidirectional DC/DC converter 12 according to the above-described embodiment mainly in terms of the control by the controller 920 and the configuration of the low-side switch 922.

The low-side switch 922 according to the comparative technique includes low-side transistors ML91 and ML92 and low-side drivers DL91 and DL92. Here, the on-resistance of the low-side transistor ML92 is smaller than the on-resistance of the low-side transistor ML91.

The controller 920 according to the comparative technique turns off the low-side transistor ML92 and operates only the low-side transistor ML91 in a step-up mode. The controller 920 turns off the low-side transistor ML91 and operates only the low-side transistor ML92 instead of the low-side transistor ML91 in a step-down mode. This achieves a higher current supply capability in the step-down mode than in the step-up mode.

Further, the controller 920 may implement a higher current supply capability in the step-down mode than in the step-up mode by operating both of the low-side transistors ML91 and ML92 in the step-down mode.

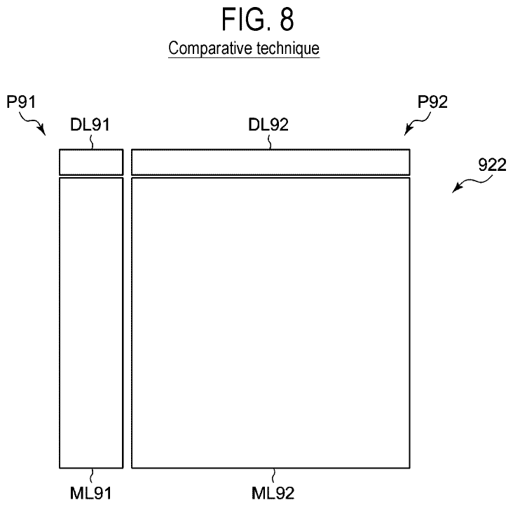

FIG. 8 is a top view of a layout of the low-side switch 922 in a semiconductor chip according to the comparative technique. As shown in FIG. 8, the size of the low-side transistor ML92 is larger than that of the low-side transistor ML91. The sizes of the low-side drivers DL91 and DL92 correspond to the size of the corresponding low-side transistor of the low-side transistors ML91 and ML92.

In the low-side switch 922 according to the comparative technique, a pair P91 of the low-side transistor ML91 and the low-side driver DL91 and a pair P92 of the low-side transistor ML92 and the low-side driver DL92 have different layouts. Therefore, it is necessary to design the layout for each of the pairs P91 and P92.

In contrast, in the low-side switch 124 according to the above-described embodiment, since the five pairs P1 to P5 have the same layout, the layout design is simple.

In addition, signal delays occur at the gates of the low-side transistors ML91 and ML92 due to parasitic capacitance and parasitic resistance. In the low-side switch 922 according to the comparative technique, since the layouts of the pairs P91 and P92 are different from each other, the signal delays at the gates of the low-side transistors ML91 and ML92 are different from each other. As a result, there is a possibility that a current will concentrate on one of the low-side transistors ML91 and ML92.

In contrast, in the low-side switch 124 according to the above embodiment, since the pairs P1 to P5 with the same layout are used, it is possible to equalize signal delays at the gates of the low-side transistors ML1 to ML5. As a result, it is possible to suppress a current from concentrating on some of the low-side transistors, thereby improving reliability.

### (Modification 1)

In the above-described embodiment, an example in which one low-side transistor is operated in each cycle in the step-up mode has been described. However, the present disclosure is not limited thereto and a plurality of low-side transistors may be operated in each cycle in the step-up mode. The number of low-side transistors operating in each cycle in the step-up mode may be less than the total number of low-side transistors.

For example, two low-side transistors may be operated in each cycle in the step-up mode. In this case, when all five low-side transistors ML1 to ML5 are operated in the step-down mode, the combined resistance of the low-side transistors in the step-down mode may be 1/2.5 of the combined resistance of the low-side transistors in the step-up mode.

By operating the plurality of low-side transistors in each cycle in the step-up mode in this way, it is possible to finely adjust a ratio between the combined resistance of the low-side transistors in the step-down mode and the combined resistance of the low-side transistors in the step-up mode. Further, even when operating the plurality of low-side transistors in the step-up mode, an operating low-side transistor may be switched in each cycle.

### Second Embodiment

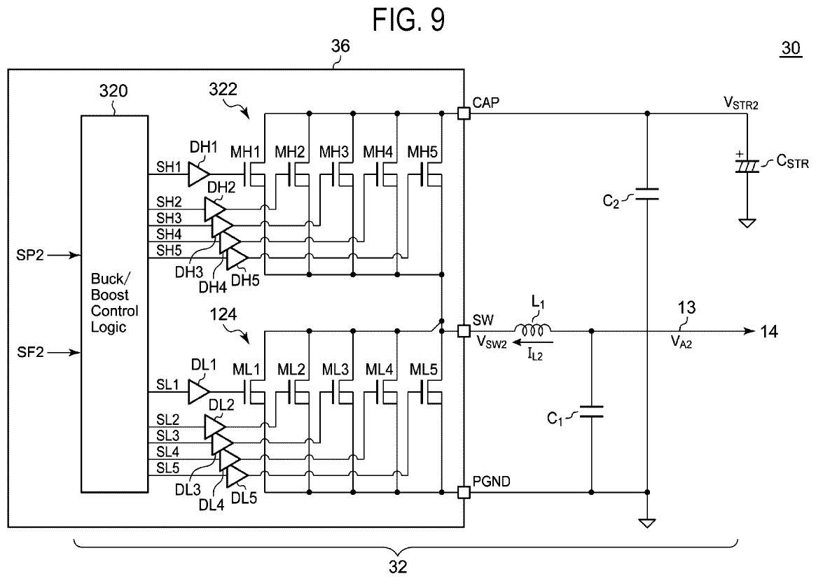

FIG. 9 is a block diagram of a power interruption protection circuit 30 for explaining a configuration of a bidirectional DC/DC converter 32 according to a second embodiment. The power interruption protection circuit 30 according to the second embodiment is different from the power interruption protection circuit 10 according to the first embodiment mainly in terms of a configuration and operation of a semiconductor device 36. The power interruption protection circuit 30 according to the second embodiment includes a bidirectional DC/DC converter 32 and a backup capacitor C_{STR}.

The bidirectional DC/DC converter 32 includes a controller 320, a high-side switch 322, a low-side switch 124, an inductor L₁, and capacitors C₁ and C₂. A portion of the bidirectional DC/DC converter 32 may be integrated in one semiconductor substrate. Specifically, the semiconductor device 36 including the controller 320, the high-side switch 322, and the low-side switch 124 may be integrated in one semiconductor substrate. The semiconductor device 36 further includes a capacitor connection terminal CAP, a switching terminal SW, and a ground terminal PGND.

The controller 320 controls operations of the high-side switch 322 and the low-side switch 124 based on a signal SP2 and a feedback signal SF2 indicating that an interruption in the supply of power from the power supply 20 to the load 22 has been detected.

The high-side switch 322 is provided between the capacitor connection terminal CAP and the switching terminal SW. The high-side switch 322 includes a plurality of high-side transistors MH1 to MH5 connected in parallel and a plurality of high-side drivers DH1 to DH5 of the same type connected in parallel. The number of pairs of high-side transistors and low-side drivers in this embodiment is five, but the number of pairs may be two to four, or six or more.

Each of the plurality of high-side transistors MH1 to MH5 in this embodiment is constituted with a transistor, and more specifically, an N-channel MOS transistor. A source of each of the high-side transistors MH1 to MH5 is connected to the switching terminal SW, and a drain of each of the high-side transistors MH1 to MH5 is connected to the capacitor connection terminal CAP.

Each of the plurality of high-side transistors MH1 to MH5 has on-resistance that can implement a sufficient current supply capacity in the step-up mode. In addition, the plurality of high-side transistors MH1 to MH5 have a combined resistance that may implement a sufficient current supply capacity in the step-down mode when all of them are in an on state. Specifically, when all of the plurality of high-side transistors MH1 to MH5 are in an on state, the combined resistance thereof is one-fifth of the on-resistance of one high-side transistor.

The controller 320 according to this embodiment controls the operations of the high-side switch 322 and the low-side switch 124 in a synchronous rectification manner in the step-up mode. Specifically, the controller 320 controls the operations of the high-side switch 322 and the low-side switch 124 so as to step up a voltage V_{A2} of the input/output line 13 connected to the load 22 and charge the backup capacitor C_{STR} by alternately repeating a charging period and a discharging period. In addition, in the step-down mode, the controller 320 controls the operations of the high-side switch 322 and the low-side switch 124 so as to step down a charging voltage V_{STR2} of the backup capacitor C_{STR} and supply the stepped down voltage to the input/output line 13.

Hereinafter, an example of the operation of the power interruption protection circuit 30 according to this embodiment will be described.

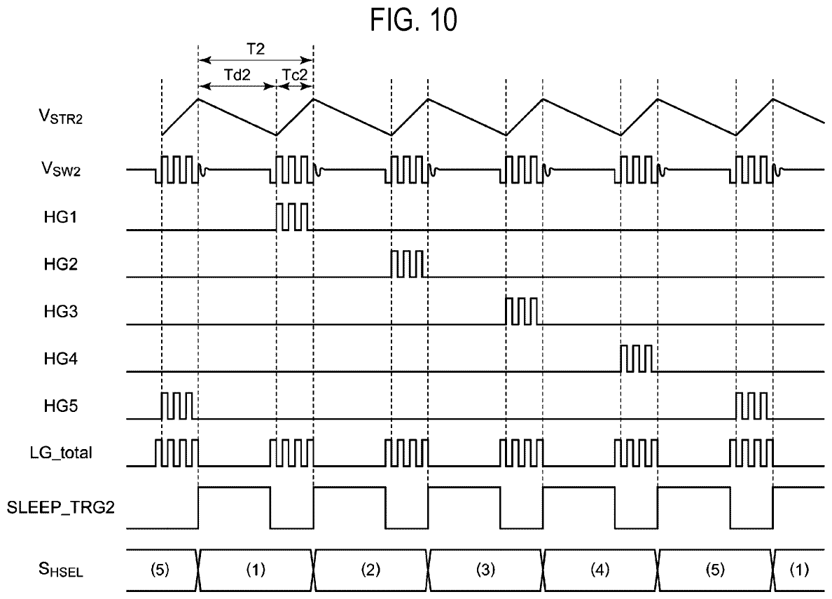

FIG. 10 is a timing chart for explaining an example of the operation of the bidirectional DC/DC converter 32 according to the second embodiment when it functions as the step-up converter. FIG. 10 shows the charging voltage V_{STR2} of the backup capacitor C_{STR}, the voltage V_{SW2} of the switching terminal SW, voltages HG1 to HG5 between the gates and the sources of the high-side transistors MH1 to MH5, the total value LG_total of voltages LG1 to LG5 between the gates and the sources of the low-side transistors ML1 to ML5, a sleep trigger SLEEP_TRG2, and a selection signal S_{HSEL} in order from the top. The sleep trigger SLEEP_TRG2 and the selection signal S_{HSEL} are internal signals of the controller 320.

In this embodiment, in the step-up mode, each of the voltages HG1 to HG5 and each of the voltages LG1 to LG5 are controlled so that a charging period Tc2 and a discharging period Td2 are alternately repeated. In the charging period Tc2, the backup capacitor C_{STR} is charged, and in the discharging period Td2, the backup capacitor C_{STR} is naturally discharged.

In this embodiment, the sleep trigger SLEEP_TRG2 alternates between a high level and a low level for each cycle T2 (=Tc2+Td2) between the charging period Tc2 and the discharging period Td2. During the period when the sleep trigger SLEEP_TRG2 is in the low level, the low-side transistors ML1 to ML5 are turned on and off. In the second embodiment, since the controller 320 performs synchronous rectification control, in the period when the sleep trigger SLEEP_TRG2 is in the low level, the high-side transistors MH1 to MH5 are also turned on and off alternately with the low-side transistors ML1 to ML5.

The controller 320 according to this embodiment operates one of the plurality of high-side transistors MH1 to MH5 during one cycle T2 of the charging period Tc2 and the discharging period Td2 in the step-up mode. Specifically, during each cycle, one of the high-side transistors MH1 to MH5 is turned on and off. This prevents the high-side transistors MH1 to MH5 from operating more than necessary.

Which of the high-side transistors MH1 to MH5 to be turned on and off are determined by the selection signal S_{HSEL}. In FIG. 10, a number k (k is 1 to 5) indicated in the selection signal S_{HSEL} indicates the high-side transistor MHK (k is 1 to 5) to be turned on and off. The low-side transistors ML1 to ML5 may operate in the same manner as in the first embodiment.

In the step-up mode, the controller 320 according to this embodiment switches which of the plurality of high-side transistors MH1 to MH5 to operate for each cycle T2 of the charging period Tc2 and the discharging period Td2. This makes it possible to distribute the operating burden to the plurality of high-side transistors MH1 to MH5, and thus improve the lifespan of the high-side transistors MH1 to MH5, as compared to when one high-side transistor is continuously operated.

Here, the plurality of high-side transistors MH1 to MH5 are referred to as first to n-th (n is an integer equal to or greater than 2) low-side transistors. The controller 320 selects an operating high-side transistor one by one from the first to n-th high-side transistors in that order every cycle T2, and operates the selected high-side transistor. In this embodiment, n=5. Specifically, as shown in FIG. 10, in one cycle following the cycle T2 in which the high-side transistor MH1 is turned on and off, the high-side transistor MH2 is turned on and off. In one cycle following this, the high-side transistor MH3 is turned on and off. In one cycle following one cycle in which the high-side transistor MH5 is turned on and off, the high-side transistor MH1 is turned on and off. This makes it possible to distribute the burden on the high-side transistors MH1 to MH5 more efficiently, and thus more effectively improve the lifespan of the high-side transistors MH1 to MH5.

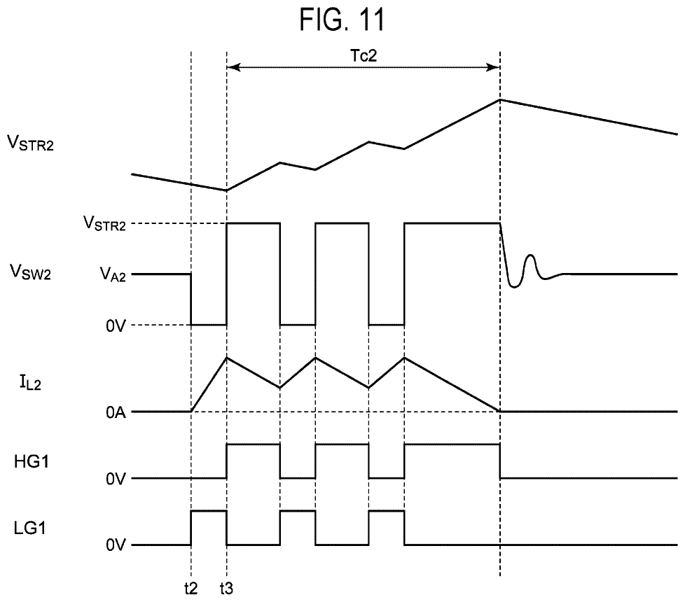

FIG. 11 is a timing chart for explaining in more detail the operation during the charging period Tc2 of the bidirectional DC/DC converter 32 functioning as the step-up converter. FIG. 11 shows the charging voltage V_{STR2} of the backup capacitor C_{STR}, the voltage V_{SW2} of the switching terminal SW, a current I_{L2} flowing through the inductor L₁, the voltage HG1 between the gate and the source of the high-side transistor MH1, and the voltage LG1 between the gate and the source of the low-side transistor ML1 in order from the top. A direction of the current I_{L2} from the input/output line 13 toward the switching terminal SW is considered positive. FIG. 11 shows the voltage HG1 between the gate and the source of the high-side

transistor MH1 and the voltage LG1 between the gate and the source of the low-side transistor ML1, but even if the voltage HG1 is replaced with the voltages HG2 to HG5, or the voltage LG1 is replaced with the voltages LG2 to LG5, the charging voltage V_{STR2}, the voltage V_{SW2}, and the current I_{L2} will change in the same manner.

As shown in FIG. 11, before timing t2 (the discharging period), the switching terminal SW is in Hi-Z, and the voltage V_{SW2} is the voltage V_{A2} of the input/output line 13. After timing t2, the high-side transistor MH1 and the low-side transistor ML1 are turned on and off alternately, causing the current I_{L2} to flow. At timing t3 when the high-side transistor MH1 is turned on, the charging period Tc2 of the backup capacitor C_{STR} starts.

In this embodiment, unlike the first embodiment, the high-side transistor HG1 operates in the step-up mode. When the high-side transistor HG1 is turned on (HG1 is at a high level) and the low-side transistor ML1 is turned off (LG1 is at a low level), the voltage V_{SW2} becomes the charging voltage V_{STR2}.

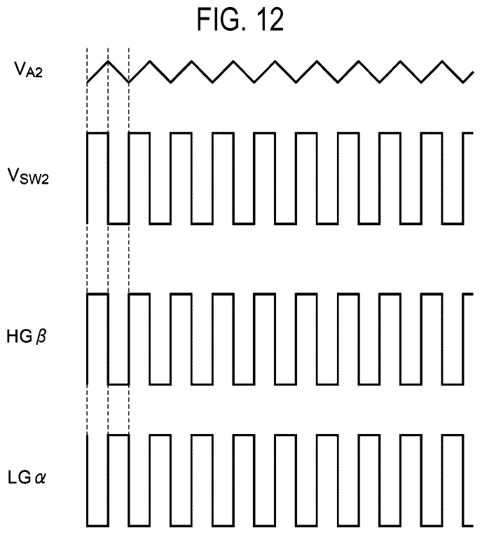

FIG. 12 is a timing chart for explaining an example of the operation of the bidirectional DC/DC converter 32 according to the second embodiment when it functions as the step-down converter. FIG. 12 shows the voltage V_{A2} of the input/output line 13, the voltage V_{SW2} of the switching terminal SW, a voltage HGβ (β: 1 to 5) between the gate and the source of a high-side transistor MHβ (β: 1 to 5), and a voltage LGα (α: 1 to 5) between the gate and the source of a low-side transistor MLα (α: 1 to 5) in order from the top.

In the step-down mode, the controller 320 controls the operations of the high-side transistors MH1 to MH5 and the low-side transistors ML1 to ML5 in a synchronous rectification manner. Specifically, the controller 320 alternately turns on and off the high-side transistors MH1 to MH5 and the low-side transistors ML1 to ML5.

In the step-down mode, the controller 320 according to this embodiment operates all of the plurality of high-side transistors MH1 to MH5 in synchronization with each other. Specifically, the controller 320 simultaneously turns on and off the high-side transistors MH1 to MH5. This makes it possible to reduce the combined resistance of the high-side transistors MH1 to MH5 as compared to when one high-side transistor is operated. As a result, it becomes possible to more reliably operate the high-side transistors MH1 to MH5 in a linear region, thereby improving the current supply capacity of the high-side switch 322.

Further, in the step-down mode, the controller 320 according to this embodiment operates all of the low-side transistors ML1 to ML5 in synchronization with each other, as in the first embodiment. This makes it possible to improve the current supply capability of the low-side switch 124.

### (Supplement)

The embodiments according to the present disclosure have been described using specific terms, but this description is merely an example to aid understanding and does not limit the scope of the present disclosure or the claims, and the scope of the present disclosure is defined by the claims. In addition to the embodiments, embodiments, examples, and modifications not described herein are also included in the scope of the present disclosure.

It is also possible to combine one or more elements of the first embodiment with one or more elements of the second embodiment. For example, it is also possible to lay out the high-side switch 322 according to the second embodiment in the same manner as the low-side switch 124 according to the first embodiment.

### (Supplementary Notes)

The technique disclosed in the present disclosure may be understood in one aspect as follows.

### (Item 1)

A bidirectional DC/DC converter includes:
a high-side switch;
a low-side switch; and
a controller capable of being switched between a step-up mode and a step-down mode and configured to generate a control signal to control operations of the high-side switch and the low-side switch so that the bidirectional DC/DC converter functions as a step-up converter in the step-up mode and functions as a step-down converter in the step-down mode,
wherein at least one of the high-side switch or the low-side switch includes a plurality of switching elements of a same type connected in parallel, and
wherein the controller operates the plurality of switching elements of the same type in conjunction with each other in the step-up mode or the step-down mode.

### (Item 2)

In the bidirectional DC/DC converter of Item 1 above, the high-side switch includes a high-side transistor constituted with a MOS transistor,
the low-side switch includes a plurality of low-side transistors constituted with MOS transistors of a same type and connected in parallel, and
the controller controls the operations of the high-side switch and the low-side switch so as to step up a voltage of an input/output line connected to a load and charge a backup capacitor by alternately repeating a charging period and a discharging period in the step-up mode, and to step down a charging voltage of the backup capacitor in the step-down mode and supply the stepped-down voltage to the input/output line.

### (Item 3)

In the bidirectional DC/DC converter of Item 2 above, the controller operates one low-side transistor of the plurality of low-side transistors in one cycle of the charging period and the discharging period in the step-up mode, and operates all of the plurality of low-side transistors in synchronization with each other in the step-down mode.

### (Item 4)

In the bidirectional DC/DC converter of Item 2 or 3 above, the controller switches which of the plurality of low-side transistors is to be operated among for each cycle of the charging period and the discharging period in the step-up mode.

### (Item 5)

In the bidirectional DC/DC converter of Item 4 above, when the plurality of low-side transistors are first to m-th (m is an integer equal to or greater than 2) low-side transistors, the controller selects an operating low-side transistor one by one from the first to m-th low-side transistors in this order for each cycle in the step-up mode and operates the selected low-side transistor.

### (Item 6)

In the bidirectional DC/DC converter of Item 1 above, the high-side switch includes a plurality of high-side transistors constituted with MOS transistors of a same type and connected in parallel,
the low-side switch includes a low-side transistor constituted with a MOS transistor, and
the controller controls the operations of the high-side switch and the low-side switch so as to step-up a voltage of an input/output line connected to a load and charge a backup capacitor by alternately repeating a charging period and a discharging period in a synchronous rectification manner in the step-up mode, and to step-down a charging voltage of the backup capacitor in the step-down mode and supply the stepped-down voltage to the input/output line.

### (Item 7)

In the bidirectional DC/DC converter of Item 6 above, the controller operates one high-side transistor of the plurality of high-side transistors in one cycle of the charging period and the discharging period in the step-up mode, and operates all of the plurality of high-side transistors in synchronization with each other in the step-down mode.

### (Item 8)

In the bidirectional DC/DC converter of Item 6 or 7 above, the controller switches which of the plurality of high-side transistors is to be operated for each cycle of the charging period and the discharging period in the step-up mode.

### (Item 9)

In the bidirectional DC/DC converter of Item 8 above, when the plurality of high-side transistors are first to n-th (n is an integer equal to or greater than 2) high-side transistors, the controller selects an operating high-side transistor one by one from the first to n-th high-side transistors in this order for each cycle in the step-up mode and operates the selected high-side transistor.

### (Item 10)

The bidirectional DC/DC converter of any one of Items 1 to 9 above further includes: a plurality of drivers of a same type that operate the plurality of corresponding switching elements of the same type, respectively, in response to the control signal.

### (Item 11)

In the bidirectional DC/DC converter of Item 10 above, the plurality of switching elements of the same type forms pairs with corresponding drivers of the plurality of drivers of the same type, respectively, and
each of the pairs is arranged side by side in one direction with a same layout.

### (Item 12)

A power interruption protection circuit includes:
the bidirectional DC/DC converter of Items 1 to 11 above; and
a backup capacitor,
wherein the controller controls the operations of the high-side switch and the low-side switch so as to step up the voltage of the input/output line connected to a load and charge the backup capacitor in the step-up mode, and to step down the charging voltage of the backup capacitor in the step-down mode and supply the stepped-down voltage to the input/output line, and
wherein a mode of the controller is switched to the step-down mode in response to detection of an interruption in supply of power from a power supply to a load.

### (Item 13)

A semiconductor device includes:
a capacitor connection terminal to which a backup capacitor is to be connected;
an input/output terminal connected to an input/output line via an inductor;
a ground terminal connected to a ground;
a high-side switch provided between the capacitor connection terminal and the input/output terminal;
a low-side switch provided between the input/output terminal and the ground terminal; and
a controller capable of being switched between a step-up mode and a step-down mode and configured to generate a control signal to control operations of the high-side switch and the low-side switch so as to step up a voltage of the input/output line and charge the backup capacitor in the step-up mode, and to step down a voltage of the backup capacitor in the step-down mode and supply the stepped-down voltage to the input/output line,
wherein at least one of the high-side switch or the low-side switch includes a plurality of switching elements of a same type connected in parallel, and
wherein the controller operates the plurality of switching elements of the same type in conjunction with each other in the step-up mode or the step-down mode.

### (Item 14)

The semiconductor device of Item 13 above is integrated in one semiconductor substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A bidirectional DC/DC converter comprising:
a high-side switch;
a low-side switch; and
a controller capable of being switched between a step-up mode and a step-down mode and configured to generate a control signal to control operations of the high-side switch and the low-side switch so that the bidirectional DC/DC converter functions as a step-up converter in the step-up mode and functions as a step-down converter in the step-down mode,
wherein at least one of the high-side switch or the low-side switch includes a plurality of switching elements of a same type connected in parallel, and
wherein the controller operates the plurality of switching elements of the same type in conjunction with each other in the step-up mode or the step-down mode.

2. The bidirectional DC/DC converter of claim 1, wherein the high-side switch includes a high-side transistor constituted with a MOS transistor,
wherein the low-side switch includes a plurality of low-side transistors constituted with MOS transistors of a same type and connected in parallel, and
wherein the controller controls the operations of the high-side switch and the low-side switch so as to step up a voltage of an input/output line connected to a load and charge a backup capacitor by alternately repeating a charging period and a discharging period in the step-up mode, and to step down a charging voltage of the backup capacitor in the step-down mode and supply the stepped-down voltage to the input/output line.

3. The bidirectional DC/DC converter of claim 2, wherein the controller operates one low-side transistor of the plurality of low-side transistors in one cycle of the charging period and the discharging period in the step-up mode, and operates all of the plurality of low-side transistors in synchronization with each other in the step-down mode.

4. The bidirectional DC/DC converter of claim 2, wherein the controller switches which of the plurality of low-side transistors is to be operated for each cycle of the charging period and the discharging period in the step-up mode.

5. The bidirectional DC/DC converter of claim 4, wherein, when the plurality of low-side transistors are first to m-th (m is an integer equal to or greater than 2) low-side transistors, the controller selects an operating low-side transistor one by one from the first to m-th low-side transistors in this order for each cycle in the step-up mode and operates the selected low-side transistor.

6. The bidirectional DC/DC converter of claim 1, wherein the high-side switch includes a plurality of high-side transistors constituted with MOS transistors of a same type and connected in parallel,
wherein the low-side switch includes a low-side transistor constituted with a MOS transistor, and
wherein the controller controls the operations of the high-side switch and the low-side switch so as to step up a voltage of an input/output line connected to a load and charge a backup capacitor by alternately repeating a charging period and a discharging period in a synchronous rectification manner in the step-up mode, and to step down a charging voltage of the backup capacitor in the step-down mode and supply the stepped-down voltage to the input/output line.

7. The bidirectional DC/DC converter of claim 6, wherein the controller operates one high-side transistor of the plurality of high-side transistors in one cycle of the charging period and the discharging period in the step-up mode, and operates all of the plurality of high-side transistors in synchronization with each other in the step-down mode.

8. The bidirectional DC/DC converter of claim 6, wherein the controller switches which of the plurality of high-side transistors is to be operated for each cycle of the charging period and the discharging period in the step-up mode.

9. The bidirectional DC/DC converter of claim 8, wherein, when the plurality of high-side transistors are first to n-th (n is an integer equal to or greater than 2) high-side transistors, the controller selects an operating high-side transistor one by one from the first to n-th high-side transistors in this order for each cycle in the step-up mode and operates the selected high-side transistor.

10. The bidirectional DC/DC converter of claim 1, further comprising: a plurality of drivers of a same type that operate the plurality of corresponding switching elements of the same type, respectively, in response to the control signal.

11. The bidirectional DC/DC converter of claim 10, wherein the plurality of switching elements of the same type forms pairs with corresponding drivers of the plurality of drivers of the same type, respectively, and
wherein each of the pairs is arranged side by side in one direction with a same layout.

12. A power interruption protection circuit comprising:
the bidirectional DC/DC converter of claim 1; and
a backup capacitor,
wherein the controller controls the operations of the high-side switch and the low-side switch so as to step up the voltage of the input/output line connected to a load and charge the backup capacitor in the step-up mode, and to step down the charging voltage of the backup capacitor in the step-down mode and supply the stepped-down voltage to the input/output line, and
wherein a mode of the controller is switched to the step-down mode in response to detection of an interruption in supply of power from a power supply to a load.

13. A semiconductor device comprising:
a capacitor connection terminal to which a backup capacitor is to be connected;
an input/output terminal to be connected to an input/output line via an inductor;
a ground terminal to be connected to a ground;
a high-side switch provided between the capacitor connection terminal and the input/output terminal;
a low-side switch provided between the input/output terminal and the ground terminal; and
a controller capable of being switched between a step-up mode and a step-down mode and configured to generate a control signal to control operations of the high-side switch and the low-side switch so as to step up a voltage of the input/output line and charge the backup capacitor in the step-up mode, and to step down a voltage of the backup capacitor in the step-down mode and supply the stepped-down voltage to the input/output line,
wherein at least one of the high-side switch or the low-side switch includes a plurality of switching elements of a same type connected in parallel, and
wherein the controller operates the plurality of switching elements of the same type in conjunction with each other in the step-up mode or the step-down mode.

14. The semiconductor device of claim 13, which is integrated in one semiconductor substrate.
